(19) United States
(12) Patent Application Publication
(10) Pub. No.: US 2007/0115715 A1
(43) Pub. Date: May 24, 2007

(54) Magnetic access memory device using perpendicular magnetization and fabrication method thereof

(76) Inventors: Ho Jun Ryu, Seoul (KR); Dong Woo Suh, Daejeon-city (KR); Mun Cheol Paek, Daejeon-city (KR); Kwang Yong Kang, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/603,463

(22) Filed: Nov. 22, 2006

(30) Foreign Application Priority Data
Nov. 23, 2005 (KR) 10-2005-0112334
May 10, 2006 (KR) 10-2006-0042011

(51) Int. Cl. G11C 11/00

(52) U.S. Cl. 365/158

(57) ABSTRACT

Provided are a magnetic random access memory (MRAM) device using perpendicular magnetization, capable of stably reducing a size of a magnetic domain, and a method of fabricating the magnetic random access memory device. The magnetic random access memory device includes at least two magnetic layers, a tunnel insulation layer, and an underlayer. Each of the two magnetic layers has a magnetic domain perpendicularly magnetized in a thickness direction. The magnetic random access memory device includes an underlayer located on one side of at least one magnetic layer, and including at least one element of elements forming at least one magnetic layer to induce exchange coupling with the magnetic layer.

### CROSS-REFERENCE TO RELATED PATENT APPLICATION

This application claims the benefit of Korean Patent Application Nos. 10-2005-0112334, filed on Nov. 23, 2005 and 10-2006-0042011, filed on May 10, 2006 in the Korean Intellectual Property Office, the disclosures of which are incorporated herein in their entirety by reference.

### BACKGROUND OF THE INVENTION

1. Field of the Invention

The present invention relates to a magnetic random access memory (MRAM) device and a fabrication method thereof, and more particularly, to a magnetic random access memory device using perpendicular magnetization and a fabrication method thereof.

2. Description of the Related Art

A magnetic random access memory device is a non-volatile memory device and uses magnetoresistance based on spin-dependent conduction peculiar to a magnetic material. Generally, the magnetic random access memory device is manufactured using a horizontal magnetization mechanism. However, some problems occur when the magnetic random access memory device is manufactured using the horizontal magnetization mechanism.

First, a magnetization direction of a magnetization spin is parallel to a surface of a stacked thin layer in a memory device using the horizontal magnetization. When a memory device having a size smaller than a micron is realized using a thin layer having the magnetization spin parallel to the surface of the thin layer, magnetization curling occurs at an end portion of a patterned memory device. The magnetization curling causes vortex magnetization, which has an adverse influence on information storing. On the other hand, an aspect ratio (a ratio of a length to a width) of at least 2 or more should be maintained in order to prevent the magnetization curling and allow desired information to be stored. The aspect ratio acts as an obstacle when a high-density integrated memory device is realized.

Second, when a magnetic random access memory device is formed using the horizontal magnetization mechanism, abnormal switching caused by a shape of the magnetic random access memory device is generated. The abnormal switching is generated by the magnetization curling, and a fluctuation in a switching field acting for the realization of switching is generated, so that information recording stability is lost. The abnormal switching is observed in the magnetic random access memory device that uses a horizontal magnetization inversion mechanism that is currently under development. The abnormal switching is a factor hindering commercialization of the magnetic random access memory device. Furthermore, a magnetoresistance curve of the magnetic random access memory device using the horizontal magnetization generally includes an offset to some extent. The offset generates crosstalk when information is recorded and thus considerably reduces information recording efficiency.

On the other hand, a magnetic random access memory device using a perpendicular magnetization mechanism does not generate the above-described problems even under low saturation magnetization. Here, the perpendicular magnetization means that magnetization is formed in a thickness direction of a magnetic layer. Also, the magnetic random access memory device using a perpendicular magnetization mechanism does not generate the magnetization curling even when the aspect ratio is 1. However, even when a high-density magnetic memory device using perpendicular magnetization is manufactured, there is a limitation to the reduction of a magnetic domain for recording because a physical phenomenon called superparamagnetism occurs when a size of the magnetic domain reduces to a size less than a critical size and thus a magnetization characteristic is lost. In particular, stability of the magnetic domain is required in the case where the size of the magnetic domain is less than a micron.

### SUMMARY OF THE INVENTION

The present invention provides a magnetic random access memory (MRAM) device using perpendicular magnetization, capable of stably reducing a size of a magnetic domain.

The present invention also provides a method of fabricating a magnetic random access memory device using perpendicular magnetization, capable of stably reducing a size of a magnetic domain.

According to an aspect of the present invention, there is provided a magnetic random access memory device using perpendicular magnetization, the magnetic random access memory device including: at least two magnetic layers each having a magnetic domain perpendicularly magnetized in a thickness direction; a tunnel insulation layer formed between the magnetic layers; and an underlayer located on one side of at least one magnetic layer, facing the tunnel insulation layer, and including at least one element of elements of at least one magnetic layer to form exchange coupling with the magnetic layer.

The underlayer may be located on one side of a spin-pinned layer or a recording layer, or simultaneously located on one side of the spin-pinned layer and the recording layer.

According to another aspect of the present invention, there is provided a method for fabricating a magnetic random access memory device, the method including: forming a recording layer having a magnetic domain perpendicularly magnetized in a thickness direction; forming a tunnel insulation layer on the recording layer; forming a spin-pinned layer on the tunnel insulation layer; and forming an underlayer located on one side of at least one of the recording layer and the spin-pinned layer, facing the tunnel insulation layer, and including at least one element of elements of the at least one layer to form exchange coupling with the at least one layer.

The forming of the underlayer may include: forming a pre-underlayer having the same composition as that of the underlayer but a different crystal structure; and applying heat to the pre-underlayer to change the underlayer such that the pre-underlayer has a crystal structure of high magnetic anisotropic energy.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a magnetic random access memory (MRAM) device according to an embodiment of the present invention;

FIG. 2 is a cross-sectional view of a magnetic random access memory device according to another embodiment of the present invention; and

FIG. 3 is a cross-sectional view of a magnetic random access memory device according to another embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their description will be omitted.

Embodiments of the present invention provide a magnetic random access memory (MRAM) device capable of suppressing magnetization loss of a magnetic domain and destruction of the magnetic domain caused by a physical phenomenon called superparamagnetism occurring when a size of a magnetic domain of a spin-pinned layer and a recording layer reduces. The embodiments of the present invention will be described with emphasis on an underlayer located in the magnetic random access memory device.

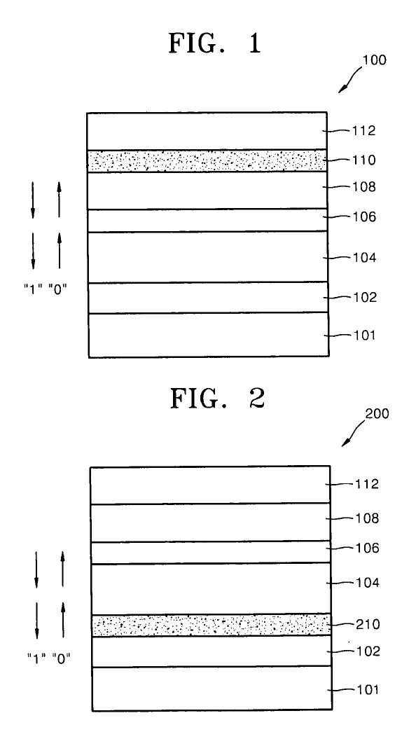

FIG. 1 is a cross-sectional view of a magnetic random access memory device 100 (referred to as a first memory device) according to an embodiment of the present invention.

Referring to FIG. 1, a first memory device 100 has a structure such that a recording layer 104 is located on a substrate 101, e.g., a conductive pad layer connected to a drain of a transistor (not shown) located in a lower side. At this point, a buffer layer 102 can be inserted therebetween to improve a coherence between the substrate 101 and the recording layer 104. A spin-pinned layer 108 is located on a tunnel insulation layer 106 facing the recording layer 104. A first underlayer 110, which constitutes a characteristic of the present invention, is formed on the spin-pinned layer 108. The first underlayer 110 is protected by a protection layer 112. The first memory device 100 may have a uniform sidewall profile and uses perpendicular magnetization oriented in one of directions opposite to each other. That is, magnetization can be defined as “1” when the magnetization is vertically oriented toward a substrate direction 101, while magnetization can be defined as “0” when the magnetization is vertically oriented toward the protection layer 112, as illustrated in FIG. 1.

According to an embodiment of the present invention, the first underlayer 110 includes of the same element as that of the spin-pinned layer 108. Therefore, the first underlayer 110 may change depending on the material of the spin-pinned layer 108. For example, when the spin-pinned layer 108 is formed of TbFeCo, the first underlayer 110 formed of FePt, which includes an element Fe of the spin-pinned layer 108, is formed on the spin-pinned layer 108. The first underlayer 110 may be at least a single thin layer formed of one material selected from the group consisting of Fe, Co, Ni, and an alloy thereof.

The first underlayer 110 is formed to contact the spin-pinned layer 108, so that exchange coupling is induced between the spin-pinned layer 108 and the first underlayer 110. The exchange coupling improves stability of the spin-pinned layer 108. Accordingly, since the size of the magnetic domain of the spin-pinned layer 108 can be reduced by the first underlayer 110, integration of the magnetic random access memory that is not influenced by superparamagnetization can improve. The exchange coupling may change depending on a thickness and composition of the first underlayer 110.

In detail, the first underlayer 110 according to an embodiment of the present invention can be phase-changed to form a crystal structure having high magnetic anisotropic energy by heat treatment during or after deposition. For example, a case where the first underlayer 110 formed of FePt is used on the spin-pinned layer 108 formed of TbFeCo will be described. At this point, a FePt layer may be a single layer formed of Fe and Pt, or a layer formed by depositing a Fe layer and a Pt layer in turns. When the FePt layer is heat-treated at a temperature range of 400 to 500° C. after deposition, a face centered cubic (fcc) structure of Fe and Pt is changed into a face centered tetragonal (fct) structure. The FePt layer, processed as described above, has a very high magnetic anisotropic energy of about 7×10⁷ erg/cm³.

The magnetic anisotropic energy is magnetically coupled to the adjoining spin-pinned layer 108 formed of TbFeCo in order to improve magnetic domain stability of the spin-pinned layer 108. That is, magnetic domain stability of the spin-pinned layer 108, according to an embodiment of the present invention, is considerably improved in comparison with the case where the first underlayer 110 is absent. Accordingly, magnetic domain stability can be maintained at a high level even when a magnetic domain of the spin-pinned layer 108 is relatively reduced, and therefore the quality of recording and reproduction signals can remarkably improve.

FIG. 2 is a cross-sectional view of a magnetic random access memory device 200 (referred to as a second memory device) according to another embodiment of the present invention. In this case, a structure of the second memory device 200 and the materials forming each layer are the same as those of the first memory device 100 except that a second underlayer 210 is located to contact a recording layer 104.

According to another embodiment, the second underlayer 210 is formed of an element of the recording layer 104. Therefore, the second underlayer 210 may change depending on the material of the recording layer 104. For example, when the recording layer 104 is formed of GbFeCo, the second underlayer 210 formed of FePt, which includes an element Fe of the recording layer 104, is formed on the recording layer 104. The second underlayer 210 may be at least a single thin layer formed of one material selected from the group consisting of Fe, Co, Ni, and an alloy thereof.

The second underlayer 210 is formed to contact the recording layer 104, so that exchange coupling is induced between the recording layer 104 and the second underlayer 210. The exchange coupling improves stability of the recording layer 104. Accordingly, since the size of the magnetic domain of the recording layer 104 can be reduced by the second underlayer 210, integration of the magnetic random access memory that is not influenced by superparamagnetization can improve.

In detail, the second underlayer 210 according to another embodiment of the present invention can be phase-changed to form a crystal structure having high magnetic anisotropic energy by heat treatment during or after deposition. For example, a case where the second underlayer 210 formed of FePt is used on the recording layer 104 formed of GbFeCo will be described. At this point, a FePt layer may be a single layer formed of Fe and Pt, or a layer formed by depositing a Fe layer and a Pt layer in turns. When the FePt layer is heat-treated at a temperature range of 400 to 500° C. after deposition, a face centered cubic (fcc) structure of Fe and Pt is changed into a face centered tetragonal (fct) structure. The FePt layer, processed as described above, has a very high magnetic anisotropic energy of about 7×10⁷ erg/cm³.

The magnetic anisotropic energy is magnetically coupled to the adjoining recording layer 104 formed of GbFeCo in order to improve magnetic domain stability of the recording layer 104. That is, the magnetic domain stability of the recording layer 104 according to another embodiment of the present invention is considerably improved in comparison with the case where the second underlayer 210 is absent. Accordingly, the magnetic domain stability can be maintained at a high level even when a magnetic domain of the recording layer 104 is relatively reduced, and therefore the quality of recording and reproduction signals can remarkably improve.

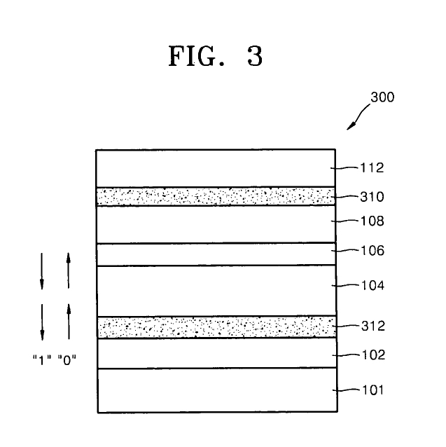

FIG. 3 is a cross-sectional view of a magnetic random access memory device 300 (referred to as a third memory device) according to another embodiment of the present invention. In this case, a structure of the second memory device 300 and the materials forming each layer are the same as those of the first memory device 100 except that a third underlayer 310 and a fourth underlayer 312 are located to contact a spin-pinned layer 108 and a recording layer 104, respectively.

Referring to FIG. 3, the third underlayer 310 contacting the spin-pinned layer 108, and the fourth underlayer 312 contacting the recording layer 104 are located facing each other. For example, the third underlayer 310 is located between the spin-pinned layer 108 and a protection layer 112, and the fourth underlayer 312 is located between the recording layer 104 and a buffer layer 102.

Here, the third underlayer 310 is formed of an element of the spin-pinned layer 108, and the fourth underlayer 312 is formed of an element of the recording layer 104. Also, the third and fourth underlayers 310 and 312 may be formed of both elements of the spin-pinned layer 108 and the recording layer 104. The third underlayer 310 performs the same function as that of the first underlayer 110 of the first memory device 100, and the fourth underlayer 312 performs the same function as that of the second underlayer 210 of the second memory device 200. Therefore, the third memory device 300 may achieve magnetic domain stability of the spin-pinned layer 108 and the recording layer 104, simultaneously.

According to a magnetic random access memory device and a fabrication method thereof according to the present invention, it is possible to provide a magnetic random access memory device capable of stably reducing the size of a magnetic domain by forming an underlayer formed of at least one element of elements of a magnetic layer on one side of at least one layer of at least two layers perpendicularly magnetized.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A magnetic random access memory (MRAM) device using perpendicular magnetization, the magnetic random access memory device comprising:
at least two magnetic layers each having a magnetic domain perpendicularly magnetized in a thickness direction;
a tunnel insulation layer formed between the magnetic layers; and
an underlayer located on one side of at least one magnetic layer, facing the tunnel insulation layer, and including at least one element of elements of at least one magnetic layer to induce exchange coupling with the magnetic layer.

2. The magnetic random access memory device of claim 1, wherein the magnetic layers include a spin-pinned layer and a recording layer.

3. The magnetic random access memory device of claim 2, wherein the underlayer is located on one side of the spin-pinned layer.

4. The magnetic random access memory device of claim 2, wherein the underlayer is located on one side of the recording layer.

5. The magnetic random access memory device of claim 2, wherein the underlayer is located on one side of the spin-pinned layer and the recording layer, simultaneously.

6. The magnetic random access memory device of claim 2, wherein the underlayer comprises at least a single thin layer formed of one material selected from Fe, Co, Ni, and an alloy thereof.

7. A method of fabricating a magnetic random access memory device, the method comprising:
forming a recording layer having a magnetic domain perpendicularly magnetized in a thickness direction;
forming a tunnel insulation layer on the recording layer;
forming a spin-pinned layer on the tunnel insulation layer; and
forming an underlayer located on one side of at least one layer of the recording layer and the spin-pinned layer, facing the tunnel insulation layer, and including at least one element of elements of the at least one layer to induce exchange coupling with the at least one layer.

8. The method of claim 7, wherein the forming of the underlayer comprises:
forming a pre-underlayer having the same composition as that of the underlayer and a different crystal structure; and
applying heat to the pre-underlayer in order to change the underlayer so that the pre-underlayer has a crystal structure having high magnetic anisotropic energy.
